(19) United States
(12) Patent Application Publication
(10) Pub. No.: US 2026/0282996 A1
(43) Pub. Date: Sep. 17, 2026

(54) ELECTRONIC DEVICE

(71) Applicant: InnoLux Corporation, Miao-Li County (TW)

(72) Inventors: I-An YAO, Miao-Li County (TW); Yu-Tsung LIU, Miao-Li County (TW); Yu-Ting TSAI, Miao-Li County (TW); Wei-Ju LIAO, Miao-Li County (TW)

(21) Appl. No.: 19/542,219

(22) Filed: Feb. 17, 2026

(30) Foreign Application Priority Data
Mar. 17, 2025 (CN) 202510310680.5

(51) Int. Cl. H10W 72/90; H10W 90/00

(52) U.S. Cl. CPC H10W 72/923; H10W 72/934; H10W 72/9445; H10W 90/724; H10W 72/952

(57) ABSTRACT

An electronic device includes a substrate, an electronic element, and a first bonding element. The substrate has an active area and a peripheral area adjacent to the active area. The electronic element is disposed on the substrate and located in the active area. The first bonding element is disposed on the substrate and located in the peripheral area, wherein the first bonding element includes a first bonding layer and a second bonding layer, the second bonding layer is disposed on the first bonding layer, and the second bonding layer covers a side surface and a top surface of the first bonding layer.

### CROSS-REFERENCE TO RELATED APPLICATIONS

This application claims the benefits of the Chinese Patent Application Serial Number 202510310680.5, filed on Mar. 17, 2025, the subject matter of which is incorporated herein by reference.

### BACKGROUND

### Field of the Disclosure

The present disclosure relates to an electronic device and, more particularly, to an electronic device having a first bonding element.

### Description of Related Art

Generally, during the manufacturing process of electronic devices, such as during the packaging process, an upper substrate and a lower substrate are aligned, and bonding elements and/or bonding materials are often used in the process to achieve the alignment step of the upper substrate and the lower substrate.

However, existing bonding elements still suffer from poor reliability and other issues, which can easily lead to a decrease in the yield of electronic devices and/or increase in production costs. Therefore, there is an urgent need to provide an improved electronic device that can alleviate and/or obviate the aforementioned defects.

### SUMMARY

The present disclosure provides an electronic device, which includes: a substrate having an active area and a peripheral area, the peripheral area being adjacent to the active area; an electronic element disposed on the substrate and located in the active area; and a first bonding element disposed on the substrate and located in the peripheral area, wherein the first bonding element includes a first bonding layer and a second bonding layer, the second bonding layer is disposed on the first bonding layer, and the second bonding layer covers a side surface and a top surface of the first bonding layer.

Other novel features of the disclosure will become more apparent from the following detailed description when taken in conjunction with the accompanying drawings.

### BRIEF DESCRIPTION OF DRAWINGS

FIG. 1A is a schematic top view of a portion of an electronic device according to an embodiment of the present disclosure;

FIG. 1B is a schematic cross-sectional view of the electronic device taken along line A-A′ of FIG. 1A;

FIG. 2 is a schematic cross-sectional view of a portion of an electronic device according to an embodiment of the present disclosure;

FIG. 3A is a schematic cross-sectional view of a portion of the first bonding layer according to an embodiment of the present disclosure;

FIG. 3B is a schematic cross-sectional view of a portion of the first bonding layer according to another embodiment of the present disclosure.

FIG. 4 is a schematic cross-sectional view of a portion of an electronic device according to an embodiment of the present disclosure;

FIG. 5 is a schematic cross-sectional view of a portion of an electronic device according to an embodiment of the present disclosure;

FIG. 6 is a schematic cross-sectional view of a portion of an electronic device according to an embodiment of the present disclosure;

FIG. 7A is a schematic top view of a portion of an electronic device according to an embodiment of the present disclosure; and

FIG. 7B is a schematic cross-sectional view of the electronic device taken along line B-B′ of FIG. 7A.

### DETAILED DESCRIPTION OF EMBODIMENT

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

It should be noted that, in the specification and claims, unless otherwise specified, having “one” element is not limited to having a single said element, but one or more said elements may be provided. In addition, in the specification and claims, unless otherwise specified, ordinal numbers, such as “first” and “second”, used herein are intended to distinguish components rather than disclose explicitly or implicitly that names of the components bear the wording of the ordinal numbers. The ordinal numbers do not imply what order a component and another component are in terms of space, time or steps of a manufacturing method. A “first” element and a “second” element may appear together in the same component, or separately in different components. The existence of an element with a larger ordinal number does not necessarily mean the existence of another element with a smaller ordinal number.

Unless otherwise defined, all terms (including technical and scientific terms) used here have the same meanings as commonly understood by those skilled in the art of the present disclosure. It is understandable that these terms, such as those defined in commonly used dictionaries, should be interpreted as having a meaning consistent with the relevant technology and the background or context of the present disclosure, rather than in an idealized or excessively formal interpretation, unless specifically defined.

It should be understood that, according to the embodiments of the present disclosure, an optical microscope (OM), a scanning electron microscope (SEM), a film thickness profiler (α-step), an ellipse thickness gauge or other suitable measurement means may be used to measure the thickness, length or width of each component, or the distance or angle between components. If the first direction is perpendicular or “substantially” perpendicular to the second direction, the angle between the first direction and the second direction may be between 80 degrees and 100 degrees. If the first direction is parallel or “substantially” parallel to the second direction, the angle between the first direction and the second direction may be between 0 degrees and 10 degrees.

The embodiments of the present disclosure may be understood together with the drawings, and the drawings of the present disclosure are also regarded as part of the disclosure description. It should be understood that the drawings of the present disclosure are not in scale and, in fact, the dimensions of elements may be arbitrarily enlarged or reduced in order to clearly illustrate features of the present disclosure.

It should be noted that the technical solutions provided in different embodiments below may be replaced, combined or mixed with each other to constitute another embodiment without violating the spirit of the present disclosure.

The electronic device of the present disclosure may include, for example, a light-emitting device, a display device, a sensing device, an antenna device, a touch device, a tiled device, or other suitable electronic devices, but not limited thereto. The display device of the present disclosure may include, for example, a light-emitting diode, a color conversion layer, or other suitable materials, or a combination thereof, but not limited thereto. The electronic device may be, for example, a bendable, stretchable, foldable, rollable, and/or flexible electronic device, but not limited thereto. The display device may be applied to,

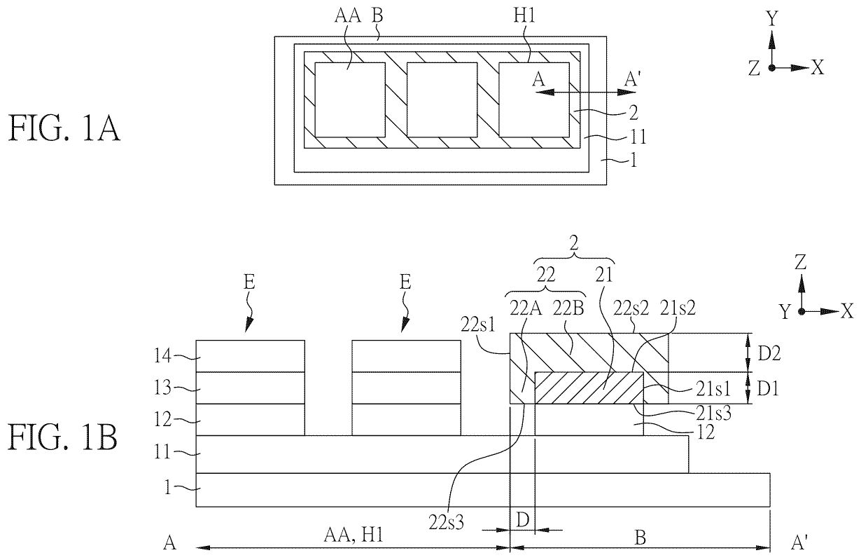

FIG. 1A is a schematic top view of a portion of an electronic device according to an embodiment of the present disclosure. FIG. 1B is a schematic cross-sectional view of the electronic device taken along line A-A′ of FIG. 1A.

In one embodiment of the present disclosure, as shown in FIG. 1A and FIG. 1B, the electronic device may include: a substrate 1 having an active area AA and a peripheral area B, the peripheral area B being adjacent to the active area AA; an electronic element E disposed on the substrate 1 and located in the active area AA; and a first bonding element 2 disposed on the substrate 1 and located in the peripheral area B, wherein the first bonding element 2 includes a first bonding layer 21 and a second bonding layer 22, the second bonding layer 22 is disposed on the first bonding layer 21, and the second bonding layer 22 covers a side surface 21s1 and a top surface 21s2 of the first bonding layer 21.

More specifically, in the top view direction Z, the first bonding element 2 may include an opening H1. The opening H1 corresponds to the active area AA of the substrate 1. That is, the projected area of the opening H1 on the substrate 1 may be substantially equal to the area of the active area AA, and the first bonding element 2 may surround the electronic element E. In the top view direction Z, the first bonding element 2 may be disposed around the active area AA. Thus, in the top view direction Z, the first bonding element 2 may have an annular structure. In a cross-sectional view, as shown in FIG. 1B, the second bonding layer 22 may include a first portion 22A and a second portion 22B. The first portion 22A covers the side surface 21s1 of the first bonding layer 21, and the second portion 22B covers the top surface 21s2 of the first bonding layer 21. The present disclosure may reduce degradation of the first bonding layer 21 caused by contact with moisture or air in the environment through the provision of the first bonding layer 21 and the second bonding layer 22, thereby improving the reliability of the first bonding element 2. In the present disclosure, the “upper surface 21s2” refers to, for example, the surface of the first bonding layer 21 facing away from the substrate 1. In the present disclosure, as shown in FIG. 1B, in a cross-sectional view, the second bonding layer 22 may include two opposing first portions 22A, with the second portion 22B disposed between the two first portions 22A, and the two first portions 22A respectively covering the two side surfaces 21s1 of the first bonding layer 21. In the present disclosure, the phrase “one component covering another component” may refer to, for example, one component completely covering another component or at least partially covering another component.

In one embodiment of the present disclosure, as shown in FIG. 1B, the electronic device may further include a first material layer 12, a second material layer 13 and a third material layer 14 disposed on a substrate 1, wherein the second material layer 13 is disposed between the first material layer 12 and the third material layer 14. The first material layer 12, the second material layer 13, and the third material layer 14 may form an electronic element E, wherein the electronic element E is electrically separated from the first bonding element 2, such that current does not flow from the electronic element E to the first bonding element 2. In the present disclosure, FIG. 1B illustrates two electronic elements E, but the present disclosure is not limited thereto. The number of electronic elements E may be adjusted (increased or decreased) as needed. Furthermore, the electronic element E in FIG. 1B illustrates three material layers (e.g., the first material layer 12, the second material layer 13 and the third material layer 14), but the present disclosure is not limited thereto. In other embodiments of the present disclosure, the number of material layers may be increased or decreased as needed. In one embodiment of the present disclosure, the electronic element E includes a sensor, a frequency transmitting unit, a signal receiving unit, a light-emitting unit, other suitable electronic components, or a combination thereof, but the present disclosure is not limited thereto. In one embodiment of the present disclosure, as shown in FIG. 1B, in the peripheral area B, the first bonding element 2 may be disposed on the first material layer 12, but the present disclosure is not limited thereto.

In the present disclosure, the material of the substrate 1 may include glass, quartz, sapphire, polyimide (PI), polypropylene (PP), polyethylene terephthalate (PET), polymethylmethacrylate (PMMA), other suitable materials, or a combination thereof, but the present disclosure is not limited thereto. In the present disclosure, the size of the active area AA is not particularly limited, and the size of the active area AA may be adjusted as needed, but the present disclosure is not limited thereto. The “size of the active area AA” refers to, for example, the maximum width or length of the active area AA in a direction (e.g., the X direction). In the present disclosure, the “peripheral area B” refers to, for example, the area outside the active area AA.

In the present disclosure, the first material layer 12, the second material layer 13 and the third material layer 14 may each include a metal, an alloy thereof, a metal oxide, an insulating material, an organic material, an inorganic material or a combination thereof. Suitable metals include, for example, gold (Au), silver (Ag), copper (Cu), palladium (Pd), platinum (Pt), titanium (Ti), molybdenum (Mo), manganese (Mn), zinc (Zn) or a combination thereof, but the present disclosure is not limited thereto. Suitable metal oxides include, for example, zinc oxide (ZnO), titanium oxide (TiO2) or a combination thereof, but the present disclosure is not limited thereto. Suitable insulating materials include, for example, silicon oxide (SiOx), silicon nitride (SiNy), silicon oxynitride (SiOxNy), other suitable materials or a combination thereof, but the present disclosure is not limited thereto. In addition, the first material layer 12, the second material layer 13 and the third material layer 14 may each be a single-layer structure or a multilayer structure.

In the present disclosure, the material of the first bonding layer 21 may include aluminum (Al), copper (Cu), an alloy thereof, or a combination thereof, but the present disclosure is not limited thereto. The material of the second bonding layer 22 may include nickel (Ni), phosphorus (P), silicon carbide (SiC), molybdenum (Mo), palladium (Pd), gold (Au), cobalt (Co), an alloy thereof, or a combination thereof, but the present disclosure is not limited thereto. In addition, the first bonding layer 21 and the second bonding layer 22 may each be a single-layer structure or a multilayer structure. In one embodiment of the present disclosure, the second bonding layer 22 may include amorphous nickel or crystalline nickel or a multilayer structure in which the two are alternately stacked. In this way, the reliability of the first bonding element 2 may be improved, but the present disclosure is not limited thereto. In the present disclosure, the thickness D1 of the first bonding layer 21 may be between 0.4 μm and 1.2 μm (i.e., 0.4 μm≤D1≤1.2 μm), for example, between 0.4 μm and 1.1 μm (i.e., 0.4 μm≤D1≤1.1 μm), between 0.4 μm and 1.0 μm (i.e., 0.4 μm≤D1≤1.0 μm), or between 0.4 μm and 0.8 μm (i.e., 0.4 μm≤D1≤0.8 μm), but the present disclosure is not limited thereto. When the thickness D1 of the first bonding layer 21 meets the above definition, delamination may be reduced, thereby increasing the reliability of the first bonding element 2. In the present disclosure, the thickness D of the first portion 22A of the second bonding layer 22 may be smaller than or equal to 100 μm, smaller than or equal to 50 μm, smaller than or equal to 30 μm, smaller than or equal to 10 μm, or smaller than or equal to 8 μm, but the present disclosure is not limited thereto. In one embodiment of the present disclosure, the thickness D2 of the second portion 22B of the second bonding layer 22 may be, for example, between 1.6 μm and 6.3 μm (i.e., 1.6 μm≤D2≤6.3 μm), between 1.6 μm and 5.3 μm (i.e., 1.6 μm≤D2≤5.3 μm), or between 1.7 μm and 5.2 μm (i.e., 1.7 μm≤D2≤5.2 μm), so as to improve the stability of the first bonding element 2. In one embodiment of the present disclosure, when the material of the second bonding layer 22 includes nickel and palladium, the thickness of the nickel layer may be between 1.5 μm and 5 μm, and the thickness of the palladium layer may be between 0.1 μm and 0.3 μm (or between 0.2 μm and 0.3 μm), so as to improve the stability of the first bonding element 2. In one embodiment of the present disclosure, when the material of the second bonding layer 22 includes gold, the thickness of the gold layer may be between 0.4 μm and 1.0 μm (i.e., 0.4 μm≤thickness≤1.0 μm), for example, between 0.4 μm and 0.8 μm (i.e., 0.4 μm≤thickness≤0.8 μm), or between 0.5 μm and 0.7 μm (i.e., 0.5 μm≤thickness≤0.7 μm), so as to improve the stability of the first bonding element 2. The “thickness D1 of the first bonding layer 21” refers to, for example, the maximum distance between the lower surface 21s3 of the first bonding layer 21 and the upper surface 21s2 of the first bonding layer 21 in the cross-sectional view, but the present disclosure is not limited thereto. The lower surface 21s3 of the first bonding layer 21 refers to, for example, the surface adjacent to the substrate 1 and in contact with the first material layer 12, the upper surface 21s2 of the first bonding layer 21 refers to, for example, the surface opposite to the lower surface 21s3 and away from the substrate 1, and the side surface 21s1 of the first bonding layer 21 is connected to the upper surface 21s2 and the lower surface 21s3 of the first bonding layer 21, respectively. The “thickness D2 of the second portion 22B of the second bonding layer 22” refers to, for example, the maximum distance between the upper surface 21s2 where the second bonding layer 22 contacts the first bonding layer 21 and the upper surface 22s2 of the second bonding layer 22 in the normal direction (e.g., the Z direction) of the substrate 1. The upper surface 22s2 of the second bonding layer 22 refers to, for example, the surface of the second bonding layer 22 away from the substrate 1. The lower surface 22s3 of the second bonding layer 22 refers to, for example, the surface opposite the upper surface 22s2 and adjacent to the substrate 1. The sidewall 22s1 of the second bonding layer 22 is connected to the upper surface 22s2 and the lower surface 22s3 of the second bonding layer 22, respectively. The “thickness D of the first portion 22A of the second bonding layer 22” refers to, for example, the maximum distance in the X-direction between the sidewall 22s1 of the second bonding layer 22 and the side surface 21s1 of the first bonding layer 21 on the same side in the cross-sectional view.

In the present disclosure, the order in which the first material layer 12, the second material layer 13, the third material layer 14, the first bonding layer 21 and the second bonding layer 22 are arranged is not particularly limited. For example, the first material layer 12, the second material layer 13 and the third material layer 14 may be formed in sequence first, and then the first bonding layer 21 and the second bonding layer 22 may be formed in sequence. However, in other embodiments, after the first material layer 12 is formed, the first bonding layer 21 may be formed first and then the other layers may be formed. In the present disclosure, each of the above layers may be formed using a suitable method. The suitable method may include, for example, electroplating, chemical plating, chemical vapor deposition, physical vapor deposition, atomic layer deposition (ALD), sputtering, lamination, coating, photolithography, lift-off technology, or a combination thereof, but the present disclosure is not limited thereto. The “coating method” may be, for example, dip coating, spin coating, roller coating, scraper coating, spray coating, or a combination thereof, but the present disclosure is not limited thereto.

In one embodiment of the present disclosure, as shown in FIG. 1A and FIG. 1B, the electronic device may further include a circuit layer 11, which is disposed on the substrate 1, and the electronic element E and the first bonding element 2 are respectively disposed on the circuit layer 11. In one embodiment of the present disclosure, the circuit layer 11 disposed in the peripheral area B may be electrically separated from the first material layer 12, but the present disclosure is not limited thereto. In the present disclosure, the circuit layer 11 may include an insulating layer, a metal layer, a semiconductor layer, a circuit, a wire, a conductor pad, a driving circuit, other suitable components, or a combination thereof. The suitable components may include passive components, active components, or a combination thereof, such as capacitors, resistors, inductors, diodes, transistors, etc., but the present disclosure is not limited thereto. The diode may include a light-emitting diode or a photodiode. The light-emitting diode may include an organic light-emitting diode (OLED), a sub-millimeter light-emitting diode (mini LED), a micro LED, or a quantum dot (QD) light-emitting diode (e.g., QLED, QDLED), or other suitable materials or a combination thereof, but the present disclosure is not limited thereto. In one embodiment of the present disclosure, the circuit layer 11 corresponding to the active area AA may include a transistor, wherein the transistor may be electrically connected to the electronic element E to drive the electronic element E.

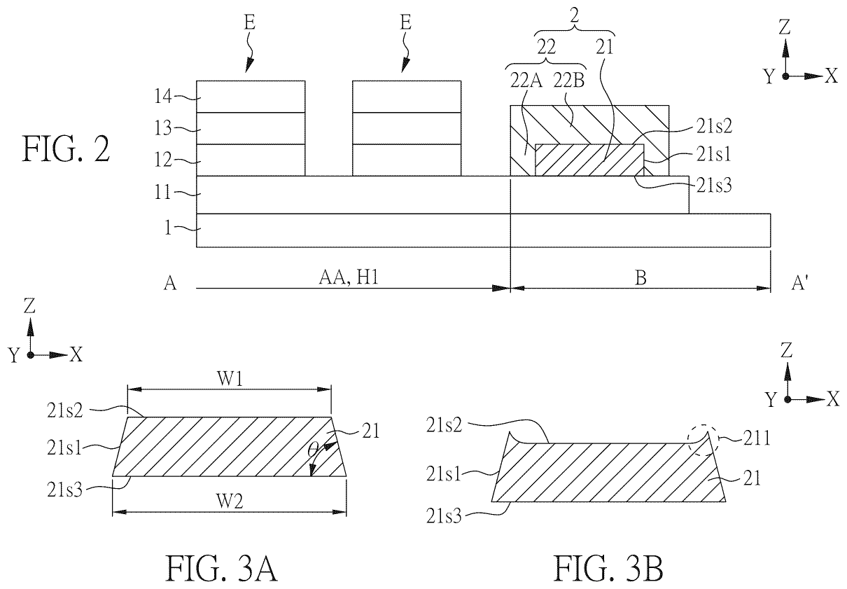

FIG. 2 is a schematic cross-sectional view of a portion of an electronic device according to an embodiment of the present disclosure. The electronic device in FIG. 2 is similar to that in FIG. 1B, except for the following differences.

In one embodiment of the present disclosure, as shown in FIG. 2, the first bonding element 2 may be disposed directly on the circuit layer 11, that is, the first bonding layer 21 may be in direct contact with the circuit layer 11, but the present disclosure is not limited thereto. Therefore, in this embodiment, the lower surface 21s3 of the first bonding layer 2 refers to, for example, a surface adjacent to the substrate 1 and in contact with the circuit layer 11.

In the present disclosure, the order in which the first material layer 12, the second material layer 13, the third material layer 14, the first bonding layer 21 and the second bonding layer 22 are formed is not particularly limited. For example, the first material layer 12, the second material layer 13 and the third material layer 14 may be formed sequentially, followed by the first bonding layer 21 and the second bonding layer 22. However, in other embodiments, the first bonding layer 21 may be formed before the first material layer 12, and then the other layers may be formed. In the present disclosure, each of the above layers may be formed using a suitable method. The suitable method is described above and will not be repeated here.

In the present disclosure, other detailed features of the electronic device may be as described above and will not be repeated here. In addition, the top view of the electronic device in FIG. 2 may be, for example, as shown in FIG. 1A and will not be repeated here.

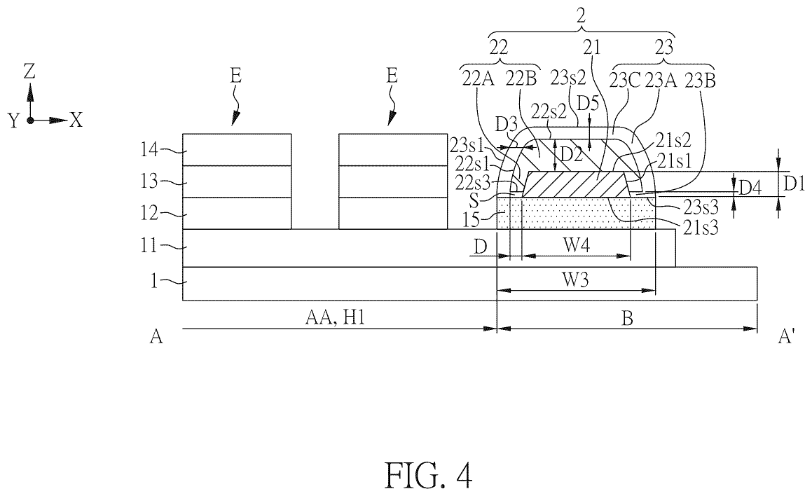

FIG. 3A is a schematic cross-sectional view of a portion of the first bonding layer 21 according to an embodiment of the present disclosure. FIG. 3B is a schematic cross-sectional view of a portion of the first bonding layer 21 according to another embodiment of the present disclosure.

In the present disclosure, the shape of the first bonding layer 21 shown in FIG. 1B and FIG. 2 is merely an example. In other embodiments of the present disclosure, the first bonding layer may also have a shape as shown in FIG. 3A or FIG. 3B.

In more detail, in one embodiment of the present disclosure, as shown in FIG. 3A, in a cross-sectional view, the first bonding layer 21 may have a trapezoidal shape, i.e., a width W2 of a lower surface 21s3 of the first bonding layer 21 may be greater than a width W1 of an upper surface 21s2 of the first bonding layer 21. In one embodiment of the present disclosure, as shown in FIG. 3A, an acute angle θ may be formed between the lower surface 21s3 of the first bonding layer 21 and the side surface 21s1 of the first bonding layer 21. The acute angle θ may be between 20° and 85°, but the present disclosure is not limited thereto.

In one embodiment of the present disclosure, as shown in FIG. 3B, in a cross-sectional view, a protrusion 211 may be provided between the upper surface 21s2 of the first bonding layer 21 and the side surface 21s1 of the first bonding layer 21. The protrusion 211 may protrude from the upper surface 21s2 of the first bonding layer 21 along the normal direction (for example, the Z direction) of the substrate 1 (as shown in FIG. 2) toward a direction away from the substrate 1 (as shown in FIG. 2).

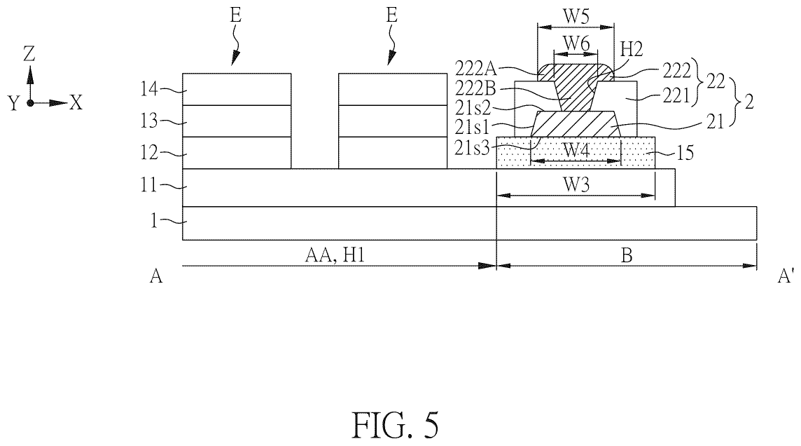

FIG. 4 is a schematic cross-sectional view of a portion of an electronic device according to an embodiment of the present disclosure. The electronic device shown in FIG. 4 is similar to that shown in FIG. 1B except for the following differences.

In one embodiment of the present disclosure, as shown in FIG. 4, the electronic device may further include another insulating layer 15 disposed between the substrate 1 and the first bonding element 2, and the width W3 of the another insulating layer 15 is greater than the width W4 of the first bonding layer 21. The “width of the component” refers to, for example, the maximum lateral dimension of the component (e.g., the maximum dimension in the X direction) in a cross-sectional view. In one embodiment of the present disclosure, as shown in FIG. 4, the width W4 of the first bonding layer 21 refers to, for example, the width of the lower surface 21s3 of the first bonding layer 21, but the present disclosure is not limited thereto. In the present disclosure, the material of the another insulating layer 15 may be the same as that of the first material layer 12, and the another insulating layer 15 may be formed simultaneously with the first material layer 12 in the same step, thereby simplifying the processing steps. The material of the another insulating layer 15 may include, for example, silicon oxide, silicon nitride, silicon oxynitride, other suitable materials, or a combination thereof, but the present disclosure is not limited thereto. In addition, the first material layer 12 and the another insulating layer 15 may be a single-layer structure or a multilayer structure.

In the present disclosure, as shown in FIG. 4, the first bonding element 2 may include a first bonding layer 21 and a second bonding layer 22 disposed on the first bonding layer 21. The composition (e.g., material, etc.) and structural features (e.g., thickness, etc.) of the first bonding layer 21 and the second bonding layer 22 may be as described in FIG. 1B and thus a detailed description is deemed unnecessary. In one embodiment of the present disclosure, the thickness D1 of the first bonding layer 21 may be between 0.4 μm and 1.2 μm (i.e., 0.4 μm≤D1≤1.2 μm), for example, between 0.4 μm and 1.1 μm (i.e., 0.4 μm≤D1≤1.1 μm), between 0.4 μm and 1.0 μm (i.e., 0.4 μm≤D1≤1.0 μm), or between 0.4 μm and 0.8 μm (i.e., 0.4 μm≤D1≤0.8 μm), but the present disclosure is not limited thereto. When the thickness D1 of the first bonding layer 21 meets the above definition, delamination may be reduced, thereby increasing the reliability of the first bonding element 2. In one embodiment of the present disclosure, the thickness D of the first portion 22A of the second bonding layer 22 may be smaller than or equal to 100 μm, smaller than or equal to 50 μm, smaller than or equal to 30 μm, smaller than or equal to 10 μm, or smaller than or equal to 8 μm, but the present disclosure is not limited thereto. In one embodiment of the present disclosure, the thickness D2 of the second portion 22B of the second bonding layer 22 may be, for example, between 1.6 μm and 6.3 μm (i.e., 1.6 μm≤D2≤6.3 μm), between 1.6 μm and 5.3 μm (i.e., 1.6 μm≤D2≤5.3 μm), or between 1.7 μm and 5.2 μm (i.e., 1.7 μm≤D2≤5.2 μm). As a result, the stability of the first bonding element 2 may be improved.

In one embodiment of the present disclosure, as shown in FIG. 4, the first bonding element 2 may further include a third bonding layer 23, wherein the third bonding layer 23 includes a first portion 23A and a second portion 23B, the first portion 23A is disposed on the second bonding layer 22, and the second portion 23B is disposed between the second bonding layer 22 and another insulating layer 15. In the present disclosure, a gap S may be provided between the second bonding layer 22 and the another insulating layer 15, or the second bonding layer 22 and the another insulating layer 15 may be in discontinuous contact (for example, the lower surface 22s3 of the second bonding layer 22 is in discontinuous contact with the lower surface 23s3 of the third bonding layer 23). Thus, the second bonding layer 22 does not directly contact the another insulating layer 15. In one embodiment of the present disclosure, as shown in FIG. 4, the third bonding layer 23 may further include a third portion 23C disposed on the second bonding layer 22, wherein the first portion 23A of the third bonding layer 23 is connected to the second portion 23B and the third portion 23C, respectively. In the present disclosure, the first portion 23A of the third bonding layer 23 refers to the portion of the third bonding layer 23 covering the sidewall 22s1 of the second bonding layer 22, the second portion 23B of the third bonding layer 23 refers to the portion of the third bonding layer 23 disposed within the gap S, and the third portion 23C of the third bonding layer 23 refers to the portion of the third bonding layer 23 covering the upper surface 22s2 of the second bonding layer 22. In the present disclosure, as shown in FIG. 4, in a cross-sectional view, the third bonding layer 23 may include two opposing first portions 23A, the third portion 23C is disposed between the two first portions 23A, and the two first portions 23A respectively cover the two sidewalls 22s1 of the second bonding layer 22.

In one embodiment of the present disclosure, as shown in FIG. 4, the second bonding layer 22 may include a curved sidewall, that is, the sidewall 22s1 of the second bonding layer 22 may have a curved shape, but the present disclosure is not limited thereto. The third bonding layer 23 may be disposed along the second bonding layer 22, so that the third bonding layer 23 has a cross-sectional shape similar to that of the second bonding layer 22, that is, the third bonding layer 23 may also include a curved sidewall 23s1. The third bonding layer 23 includes a lower surface 23s3 adjacent to the substrate 1 and in contact with another insulating layer 15, and an upper surface 23s2 opposite to the lower surface 23s3 and away from the substrate 1, wherein the curved sidewall 23s1 of the third bonding layer 23 may be connected to the upper surface 23s2 and the lower surface 23s3 of the third bonding layer 23, respectively. In one embodiment of the present disclosure, as shown in FIG. 4, the projection of the upper surface 23s2 of the third bonding layer 23 on the substrate 1 may overlap the projection of the upper surface 21s2 of the first bonding layer 21 on the substrate 1. In other words, the projected area of the upper surface 23s2 of the third bonding layer 23 on the substrate 1 may be smaller than or equal to the projected area of the upper surface 21s2 of the first bonding layer 21 on the substrate 1. In one embodiment of the present disclosure, as shown in FIG. 4, the projection of the curved sidewall 23s1 of the third bonding layer 23 on the substrate 1 may be located outside the projection of the upper surface 21s2 of the first bonding layer 21 on the substrate 1. In other words, in the normal direction of the substrate 1 (e.g., the Z direction), the projection of the curved sidewall 23s1 of the third bonding layer 23 on the substrate 1 does not overlap with the projection of the upper surface 21s2 of the first bonding layer 21 on the substrate 1. In one embodiment of the present disclosure, as shown in FIG. 4, the projection of the upper surface 22s2 of the second bonding layer 22 on the substrate 1 may overlap the projection of the upper surface 21s2 of the first bonding layer 21 on the substrate 1. In other words, the projected area of the upper surface 22s2 of the second bonding layer 22 on the substrate 1 may be smaller than or equal to the projected area of the upper surface 21s2 of the first bonding layer 21 on the substrate 1. In one embodiment of the present disclosure, as shown in FIG. 4, the projection of the sidewall 22s1 of the second bonding layer 22 on the substrate 1 may be located outside the projection of the upper surface 21s2 of the first bonding layer 21 on the substrate 1. In other words, in the normal direction of the substrate 1 (e.g., the Z direction), the projection of the sidewall 22s1 of the second bonding layer 22 on the substrate 1 does not overlap with the projection of the upper surface 21s2 of the first bonding layer 21 on the substrate 1.

In the present disclosure, the material of the third bonding layer 23 may include nickel, phosphorus, silicon carbide, molybdenum, palladium, gold, cobalt, an alloy thereof, or a combination thereof, but the present disclosure is not limited thereto. The third bonding layer 23 may be a single-layer structure or a multilayer structure. In addition, the method for forming the third bonding layer 23 may include, for example, electroplating, chemical plating, chemical vapor deposition, physical vapor deposition, atomic layer deposition (ALD), sputtering, lamination, coating, photolithography, lift-off technology, or a combination thereof, but the present disclosure is not limited thereto. In the present disclosure, the thickness D3 of the first portion 23A of the third bonding layer 23 may be greater than the thickness D4 of the second portion 23B of the third bonding layer 23. The “thickness D3 of the first portion 23A of the third bonding layer 23” refers to, for example, the maximum distance in the X direction between the sidewall 22s1 of the second bonding layer 22 and the curved sidewall 23s1 of the third bonding layer 23 on the same side in the cross-sectional view. The “thickness D4 of the second portion 23B of the third bonding layer 23” refers to, for example, the maximum distance between the lower surface 23s3 of the third bonding layer 23 and the lower surface 22s3 of the second bonding layer 22 in the cross-sectional view. When the thickness of the third bonding layer 23 meets the above description, the stability of the first bonding element 2 may be improved. In the present disclosure, the thickness D5 of the third portion 23C of the third bonding layer 23 may be between 0.4 μm and 1.0 μm (i.e., 0.4 μm≤D5≤1.0 μm), for example, between 0.4 μm and 0.8 μm (i.e., 0.4 μm≤D5≤0.8 μm), or between 0.5 μm and 0.7 μm (i.e., 0.5 μm≤D5≤0.7 μm), but the present disclosure is not limited thereto. The “thickness D5 of the third portion 23C of the third bonding layer 23” refers to, for example, the maximum distance between the upper surface 22s2 of the second bonding layer 22 where the third bonding layer 23 contacts the upper surface 23s2 of the third bonding layer 23 in the normal direction of the substrate 1 (for example, the Z direction).

In the present disclosure, other detailed features of the electronic device may be as described above and will not be repeated here.

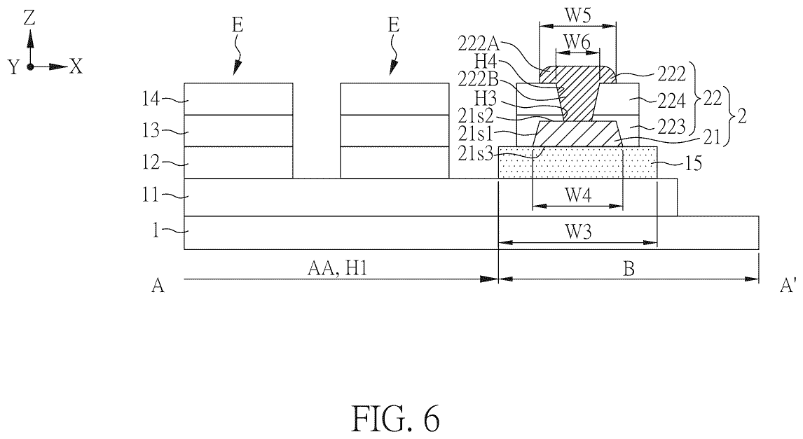

FIG. 5 is a schematic cross-sectional view of a portion of an electronic device according to an embodiment of the present disclosure. The electronic device shown in FIG. 5 is similar to that shown in FIG. 1B except for the following differences.

In one embodiment of the present disclosure, as shown in FIG. 5, the second bonding layer 22 may include an insulating layer 221 and a metal layer 222. The insulating layer 221 is disposed on the first bonding layer 21, and the metal layer 222 is disposed on the insulating layer 221. The insulating layer 221 covers the side surface 21s1 of the first bonding layer 21 and includes an opening H2. The opening H2 exposes a portion of the upper surface 21s2 of the first bonding layer 21. The metal layer 222 of the second bonding layer 22 contacts the upper surface 21s2 of the first bonding layer 21 through the opening H2. More specifically, the metal layer 222 of the second bonding layer 22 may include a first portion 222A and a second portion 222B. The first portion 222A may cover the opening H2, and the second portion 222B may be disposed in the opening H2. As a result, it is able to reduce degradation of the first bonding layer 21 caused by contact with moisture, air, or solvents, thereby improving the reliability of the first bonding element 2.

In the present disclosure, the material of the insulating layer 221 may be the same as that of the third material layer 14, and the insulating layer 221 may be formed simultaneously with the third material layer 14 in the same step, which may simplify the processing steps. The material of the insulating layer 221 may include, for example, silicon oxide, silicon nitride, silicon oxynitride, other suitable materials or a combination thereof, but the present disclosure is not limited thereto. In the present disclosure, the material of the metal layer 222 may include nickel, molybdenum, palladium, gold, cobalt, an alloy thereof or a combination thereof, but the present disclosure is not limited thereto. In the present disclosure, the width W5 of the first portion 222A of the metal layer 222 may be greater than or equal to the width W6 of the second portion 222B. The “width W5 of the first portion 222A of the metal layer 222” refers to, for example, the maximum lateral dimension (e.g., the maximum dimension in the X direction) of the first portion 222A of the metal layer 222 in the cross-sectional view. The “width of the second portion 222B of the metal layer 222” refers to, for example, the maximum lateral dimension (e.g., the maximum dimension in the X-direction) of the second portion 222B of the metal layer 222 in a cross-sectional view. In one embodiment of the present disclosure, as shown in FIG. 5, the opening H2 may have an inverted trapezoidal shape in a cross-sectional view. However, the present disclosure is not limited thereto. In other embodiments, the opening H2 may have a rectangular, right trapezoidal, or other irregular shape.

In one embodiment of the present disclosure, as shown in FIG. 5, the electronic device may further include another insulating layer 15, which is disposed between the substrate 1 and the first bonding element 2, and the width W3 of the another insulating layer 15 is greater than the width W4 of the first bonding layer 21. In the present disclosure, the material of the another insulating layer 15 may be the same as that of the first material layer 12, and the another insulating layer 15 may be formed simultaneously with the first material layer 12 in the same step, thereby simplifying the processing steps. The material of the another insulating layer 15 may, for example, include silicon oxide, silicon nitride, silicon oxynitride, other suitable materials, or a combination thereof, but the present disclosure is not limited thereto. The “width of the component” refers to, for example, the maximum lateral dimension of the component in the cross-sectional view (e.g., the maximum dimension in the X direction).

In the present disclosure, other detailed features of the electronic device may be as described above and will not be repeated here.

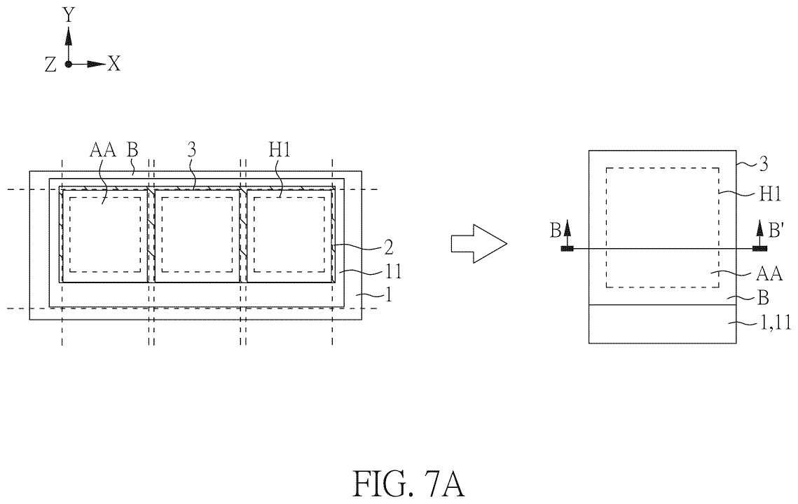

FIG. 6 is a schematic cross-sectional view of a portion of an electronic device according to an embodiment of the present disclosure. The electronic device in FIG. 6 is similar to that in FIG. 1B except for the following differences.

In one embodiment of the present disclosure, as shown in FIG. 6, the second bonding layer 22 may include a fourth material layer 223, a fifth material layer 224 and a metal layer 222. The fourth material layer 223 and the fifth material layer 224 are disposed on the first bonding layer 21, and the metal layer 222 is disposed on the fourth material layer 223 and the fifth material layer 224. The fourth material layer 223 covers the side surface 21s1 of the first bonding layer 21, and is provided with a first opening H3. The first opening H3 exposes a portion of the top surface 21s2 of the first bonding layer 21. The fifth material layer 224 is disposed on the fourth material layer 223, and is provided with a second opening H4. The second opening H4 is connected to the first opening H3. The metal layer 222 of the second bonding layer 22 contacts the top surface 21s2 of the first bonding layer 21 through the first opening H3 and the second opening H4. More specifically, the metal layer 222 of the second bonding layer 22 may include a first portion 222A and a second portion 222B. The first portion 222A may cover the second opening H4, and the second portion 222B may be disposed within the first opening H3 and the second opening H4. As a result, it is able to reduce degradation of the first bonding layer 21 caused by contact with moisture, air, or solvents, thereby improving the reliability of the first bonding element 2.

In the present disclosure, the material of the fourth material layer 223 may be the same as that of the second material layer 13, and the fourth material layer 223 may be formed simultaneously with the second material layer 13 in the same step, thereby simplifying the processing steps. The material of the fifth material layer 224 may be the same as that of the third material layer 14, and the fifth material layer 224 may be formed simultaneously with the third material layer 14 in the same step, thereby simplifying the processing steps. The materials of the second material layer 13 and the third material layer 14 may be as described above and will not be repeated here. In the present disclosure, the material of the metal layer 222 may include nickel, molybdenum, palladium, gold, cobalt, an alloy thereof, or a combination thereof, but the present disclosure is not limited thereto. In the present disclosure, the width W5 of the first portion 222A of the metal layer 222 may be greater than or equal to the width W6 of the second portion 222B. The “width W5 of the first portion 222A of the metal layer 222” refers to, for example, the maximum lateral dimension (e.g., the maximum dimension in the X direction) of the first portion 222A of the metal layer 222 in the cross-sectional view. The “width W6 of the second portion 222B of the metal layer 222” refers to, for example, the maximum lateral dimension (e.g., the maximum dimension in the X-direction) of the second portion 222B of the metal layer 222 in the cross-sectional view. In one embodiment of the present disclosure, as shown in FIG. 6, the first opening H3 and the second opening H4 may collectively form an inverted trapezoidal shape in the cross-sectional view. However, the present disclosure is not limited thereto. In other embodiments, the first opening H3 and the second opening H4 may collectively form a rectangular, right trapezoidal, or other irregular shape.

In one embodiment of the present disclosure, as shown in FIG. 6, the electronic device may further include another insulating layer 15, which is disposed between the substrate 1 and the first bonding element 2, and the width W3 of the another insulating layer 15 is greater than the width W4 of the first bonding layer 21. In the present disclosure, the material of the another insulating layer 15 may be the same as that of the first material layer 12, and the another insulating layer 15 may be formed simultaneously with the first material layer 12 in the same step, thereby simplifying the processing steps. The material of the another insulating layer 15 may, for example, include silicon oxide, silicon nitride, silicon oxynitride, other suitable materials, or a combination thereof, but the present disclosure is not limited thereto. The “width of the component” refers to, for example, the maximum lateral dimension of the component in the cross-sectional view (e.g., the maximum dimension in the X direction).

In the present disclosure, other detailed features of the electronic device may be described as above and will not be repeated here.

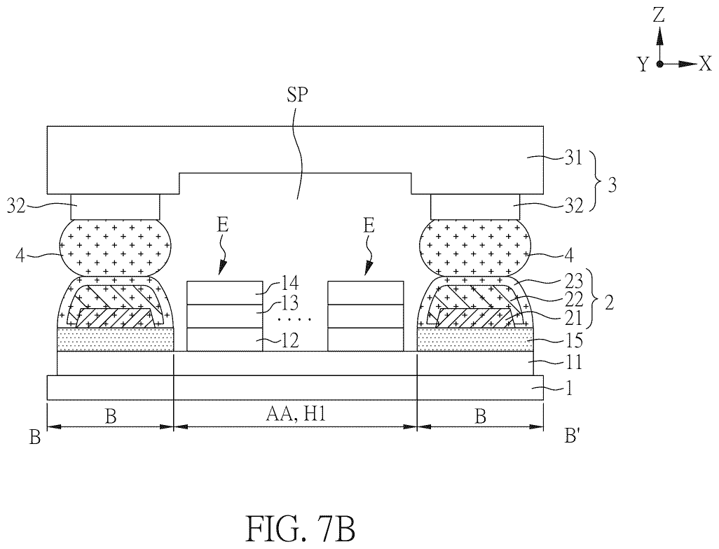

FIG. 7A is a schematic top view of a portion of an electronic device according to an embodiment of the present disclosure. FIG. 7B is a schematic cross-sectional view of the electronic device taken along line B-B′ of FIG. 7A.

In one embodiment of the present disclosure, as shown in FIG. 7A and FIG. 7B, a cover plate 3 is provided and the cover plate 3 is disposed corresponding to the opening H1 of the first bonding element 2 shown in FIG. 1A. Next, a bonding material 4 is applied between the substrate 1 and the cover plate 3, allowing the cover plate 3 to be connected to the substrate 1 through the bonding material 4. Thereafter, the substrate 1 and the circuit layer 11 are cut along the dotted lines, thereby forming the electronic device shown on the right side of FIG. 7A and in FIG. 7B. Therefore, as shown in FIG. 7B, the electronic device may further include a cover plate 3 and a bonding material 4, and the cover plate 3 may be connected to the substrate 1 through the bonding material 4, thereby achieving the purpose of assembling the cover plate 3 to the substrate 1. In more detail, the cover plate 3 includes a body 31 and a second bonding element 32, and the second bonding element 32 is disposed between the body 31 and the bonding material 4. The first bonding element 2 and the second bonding element 32 may be bonded to each other through the bonding material 4, thereby forming a sealed space SP between the substrate 1 and the cover plate 3. In the present disclosure, the bonding material 4 may flow along the position of the first bonding element 2 and/or the second bonding element 32, which may reduce the possibility of the bonding material 4 overflowing into the sealed space SP, thereby reducing the overflowing bonding material 4 from affecting or interfering with the shape of the components (such as the electronic elements E) disposed in the active area AA.

In the present disclosure, the material of the cover plate 3 may include silicon, germanium (Ge), zinc sulfide (ZnS), zinc selenide (ZnSe), gallium arsenide (GaAs), chalcogenide, or a combination thereof, but the present disclosure is not limited thereto. The first bonding element 2 in FIG. 7B is illustrated with the structure of FIG. 4 as an example. Therefore, the features of the first bonding element 2 may refer to the above description and will not be repeated here. However, the present disclosure is not limited thereto. In other embodiments of the present disclosure, the structure of the first bonding element 2 may be as shown in any of FIG. 1B to FIG. FIG. 6, and will not be repeated here. In the present disclosure, the second bonding element 32 may have the same or different structure as the first bonding element 2, that is, the structure of the second bonding element 32 may be selectively similar to that of the first bonding element 2 as shown in FIG. 1B to FIG. FIG. 6, and will not be repeated here. In the present disclosure, the bonding material 4 may include solder, solder, solder paste, or a combination thereof, but the present disclosure is not limited thereto. In the present disclosure, the bonding material 4 may include tin, a tin alloy, or a combination thereof, but the present disclosure is not limited thereto. In the present disclosure, the sealed space SP may be in a vacuum state or a near-vacuum state to reduce interference of other external environments (such as moisture, air, etc.) on the electronic elements in the active area AA.

In one embodiment of the present disclosure, as shown in FIG. 7B, the electronic device may further include another insulating layer 15 disposed between the substrate 1 and the first bonding element 2. In the present disclosure, the material and other features of the another insulating layer 15 may be as described above and will not be repeated here. Furthermore, other detailed features of the electronic device may also be as described above and will not be repeated here.

The present disclosure may reduce degradation of the first bonding layer 21 caused by contact with moisture or air in the environment by providing the first bonding layer 21 and the second bonding layer 22, thereby improving the reliability of the first bonding element 2. Furthermore, the first bonding element 2 may optionally include a third bonding layer 23 to enhance the stability of the first bonding element 2.

The aforementioned specific embodiments should be construed as merely illustrative, and not limiting the rest of the present disclosure in any way.

1. An electronic device, comprising:
a substrate having an active area and a peripheral area, the peripheral area being adjacent to the active area;
an electronic element disposed on the substrate and located in the active area; and
a first bonding element disposed on the substrate and located in the peripheral area, wherein the first bonding element includes a first bonding layer and a second bonding layer, the second bonding layer is disposed on the first bonding layer, and the second bonding layer covers a side surface and a top surface of the first bonding layer.

2. The electronic device as claimed in claim 1, wherein the second bonding layer includes a first portion, the first portion covers the side surface of the first bonding layer, and a thickness of the first portion is smaller than or equal to 100 μm.

3. The electronic device as claimed in claim 1, wherein a material of the first bonding layer includes aluminum, copper, an alloy thereof, or a combination thereof.

4. The electronic device as claimed in claim 1, wherein a material of the second bonding layer includes nickel, phosphorus, silicon carbide, molybdenum, palladium, gold, cobalt, an alloy thereof, or combinations thereof.

5. The electronic device as claimed in claim 1, wherein the second bonding layer includes a curved sidewall.

6. The electronic device as claimed in claim 1, wherein the second bonding layer includes an insulating layer and a metal layer, the insulating layer is disposed on the first bonding layer, the metal layer is disposed on the insulating layer, the insulating layer covers the side surface of the first bonding layer and is provided with an opening that exposes a portion of the top surface of the first bonding layer, and the metal layer of the second bonding layer contacts the top surface of the first bonding layer through the opening.

7. The electronic device as claimed in claim 1, further comprising a further insulating layer disposed between the substrate and the first bonding element, wherein a width of the further insulating layer is greater than a width of the first bonding layer.

8. The electronic device as claimed in claim 7, wherein the first bonding element further includes a third bonding layer, the third bonding layer includes a first portion and a second portion, the first portion is disposed on the second bonding layer and covers a sidewall of the second bonding layer, and the second portion is disposed between the second bonding layer and the further insulating layer.

9. The electronic device as claimed in claim 8, wherein a thickness of the first portion of the third bonding layer is greater than a thickness of the second portion of the third bonding layer.

10. The electronic device as claimed in claim 1, wherein, in a cross-sectional view, a width of a lower surface of the first bonding layer is greater than a width of an upper surface of the first bonding layer.

11. The electronic device as claimed in claim 1, further comprising a cover and a bonding material, the cover being connected to the substrate via the bonding material.
